(19) United States
(12) Patent Application Publication
(10) Pub. No.: US 2014/0335672 A1
(43) Pub. Date: Nov. 13, 2014

(54) PROCESS FOR MANUFACTURING SEMICONDUCTOR TRANSISTOR DEVICE

(71) Applicant: UNITED MICROELETRONICS CORPORATION, Hsinchu (TW)

(72) Inventor: Chung-Chih CHEN, Hsinchu City (TW)

(73) Assignee: UNITED MICROELETRONICS CORPORATION, Hsinchu (TW)

(21) Appl. No.: 13/889,358

(22) Filed: May 8, 2013

(51) Int. Cl. H01L 29/66; H01L 21/762

(52) U.S. Cl. CPC H01L 29/66666; H01L 21/76224
USPC 438/270; 438/424

(57) ABSTRACT

A process for manufacturing a semiconductor transistor device is provided. The process comprises steps of providing a substrate; forming a patterned hard mask on the substrate; forming a spacer on a sidewall of the patterned hard mask; forming a trench by removing a portion of the substrate not being covered by the patterned hard mask and the spacer; and filling a conductive material into the trench.

### FIELD OF THE INVENTION

The present invention relates to a process for manufacturing semiconductor device, and more particularly to a process for manufacturing semiconductor transistor devices.

### BACKGROUND OF THE INVENTION

As the demand on the device integration is gradually increased, the dimensions of each semiconductor transistor device keeping on shrinkage. However, the process for forming semiconductor transistor devices becomes harder to do as the dimensions thereof are shrinking. For instance, forming a trench in a substrate easily results in the partial deformation of the substrate; or it is difficult to fill a material into a trench completely because the opening of the trench is too narrow. The above drawbacks may impair the performance of the fabricated transistor devices.

Therefore, there is a need to develop a process capable of manufacturing a semiconductor transistor device with enhanced performance.

### SUMMARY OF THE INVENTION

In accordance with an aspect of the present invention, a process for manufacturing a semiconductor transistor device is provided in order to enhance the performance of the semiconductor transistor device. In an embodiment, a substrate is provided. Then a patterned hard mask is formed on the substrate. Next, a spacer is formed on a sidewall of the patterned hard mask. After that, a trench is formed by removing a portion of the substrate not covered by the patterned hard mask and the spacer. Finally, a conductive material is filled into the trench.

In one embodiment of the present invention, the step of forming the spacer includes for forming a conformal dielectric layer over the substrate with the patterned hard mask; and the spacer is formed on the sidewall of the patterned hard mask by anisotropically etching the dielectric layer.

In one embodiment of the present invention, the substrate is anisotropically etched with a specified gas etchant, which results in an etching rate of the substrate anisotropically 10 to hundreds of times higher than an etching rate of the spacer.

In one embodiment of the present invention, the spacer has a rectangular cross section, and a thickness of the spacer extending from the patterned hard mask is equal or less than 150 angstroms.

In one embodiment of the present invention, the spacer has a triangular or trapezoid cross section, and a thickness of the spacer extending from the patterned hard mask is equal or less than 150 angstroms.

In one embodiment of the present invention, before the step of filling the conductive material, the manufacturing process further includes steps of forming a sacrificial layer on an inner surface of the trench by conducting a reaction between an oxygen gas with the substrate, exposing the inner surface of the trench by removing the sacrificial layer, and forming a first oxide layer on the inner surface of the trench.

In one embodiment of the present invention, after the step of filling the conductive material, the manufacturing process further includes performing steps of a planarization process and an etching back process of the conductive material to remove a top portion of the conductive material so as to create a recess of tens to hundreds of nanometers in depth, etching the conductive material under the recess to form a gate structure, and filling a second oxide layer into the trench to cover the gate structure.

In one embodiment of the present invention, the trench is formed in a gate region for forming a gate structure, and the manufacturing process further includes steps of forming a drain structure in a drain region of the substrate disposed at a first side of the gate region and extending underneath the gate region; and forming a source structure in a source region of the substrate at a second side of the gate region, thereby manufacturing a PTMOS device.

In one embodiment of the present invention, the manufacturing process further includes steps of doping the gate structure, wherein the gate structure is made of polysilicon; the substrate is doped as a first conductivity type; and the source/drain structure is doped as a second conductivity type, wherein the first conductivity type is different from the second conductivity type.

In one embodiment of the present invention, a material for forming the spacer is selected from a group consisting of oxide, nitride, silicon carbide and silicon oxynitride, and a depth of the trench ranges between thousands of angstroms and tens of micrometers.

In one embodiment of the present invention, the trench is a through hole penetrating the substrate.

In accordance with another aspect of the present invention, a process for manufacturing a semiconductor transistor device is provided in order to improve the performance of the semiconductor transistor device. In an embodiment, a substrate is provided. Then a patterned hard mask is formed over the substrate. Next, a spacer is formed on a sidewall of the patterned hard mask. After that, a trench is formed by removing a portion of the substrate not being covered by the patterned hard mask and the spacer. Finally, a trench isolation structure is formed by filling a dielectric material into the trench.

In one embodiment of the present invention, the step of forming the spacer includes forming a conformal dielectric layer over the patterned hard mask; and forming the spacer on the sidewall of the patterned hard mask by anisotropically etching the dielectric layer.

In one embodiment of the present invention, the substrate is anisotropically etched with a specified gas etchant, which results in an etching rate of the substrate 10 to hundreds of times higher than an etching rate of the spacer.

In one embodiment of the present invention, the spacer has a rectangular cross section, and the thickness of the spacer extending from the patterned hard mask is equal or less than 150 angstroms.

In one embodiment of the present invention, the spacer has a triangular or trapezoid cross section, and the thickness of the spacer extending from the patterned hard mask is equal or less than 150 angstroms.

In one embodiment of the present invention, a material for forming the spacer is selected from a group consisting of silicon dioxide, silicon nitride, silicon carbide, or silicon oxynitride, and a depth of the trench ranges between thousands of angstroms and tens of micrometers.

In one embodiment of the present invention, the trench isolation structure is disposed in a FinFET device or a CMOS device.

### BRIEF DESCRIPTION OF THE DRAWINGS

The present invention will become more readily apparent to those ordinarily skilled in the art after reviewing the following detailed description and accompanying drawings, in which:

FIG. 1A˜FIG. 1D are cross-sectional views, combined to illustrate some steps of a process for forming a semiconductor transistor device according to one embodiment of the present invention.

FIG. 2˜FIG. 5 are cross-sectional views, combined to illustrate some steps of a process for forming a semiconductor transistor device according to another embodiment of the present invention.

FIG. 6˜FIG. 11 are cross-sectional views, combined to illustrate some steps of a process for forming a planer-trench power MOS device according to one embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

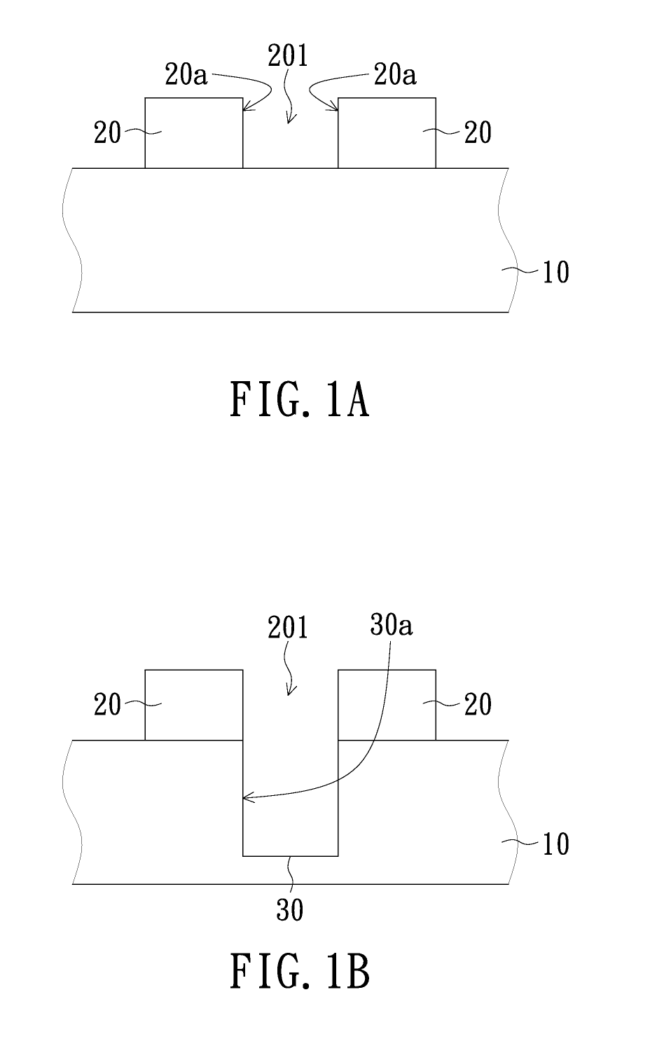

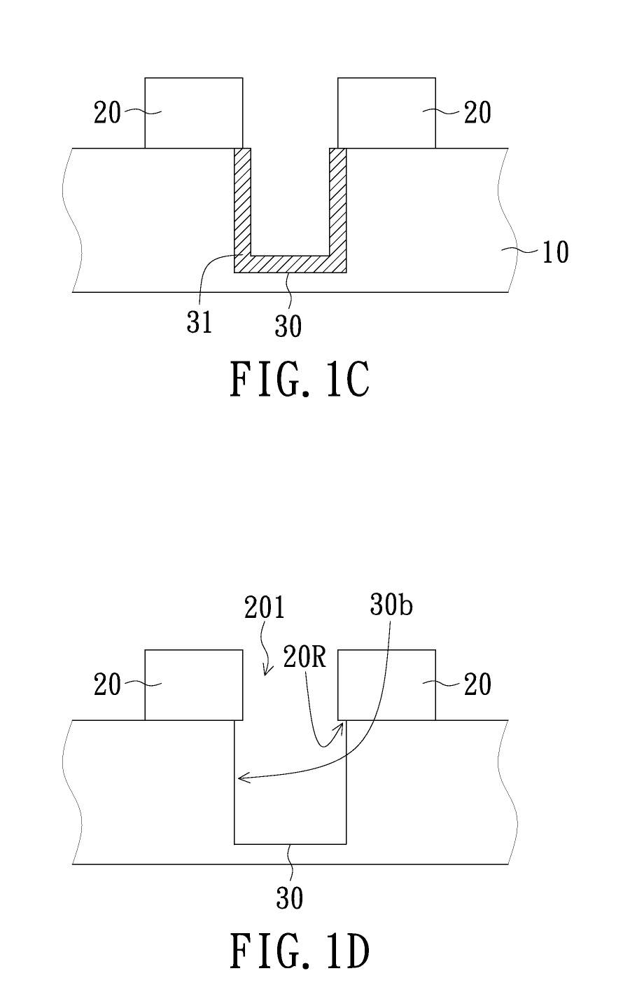

With reference to FIG. 1A˜FIG. 1D, some steps of a process for forming a semiconductor transistor device according to one embodiment of the present invention are schematically illustrated in cross-sectional view. Firstly, a substrate 10 is provided. A material of the substrate 10 may be a semiconductor material, e.g. silicon, germanium, or silicon germanium. Then, a patterned hard mask layer 20 is formed on the substrate 10. This step includes of forming a hard mask layer on the substrate 10; and then a patterning process of the hard mask layer is performed, thereby forming the patterned hard mask layer 20 which for example, may have an opening 201 for exposing a portion of the surface of the substrate 10. Next, a trench 30 is formed by removing a portion of the substrate 10 under the opening 201, as shown in FIG. 1B. In this embodiment, the hard mask layer may be a single dielectric layer or multiple dielectric layers, wherein a material of each dielectric layer may be selected from a group consisting of silicon dioxide, silicon nitride, silicon carbide and silicon oxynitride.

The trench 30 in this embodiment of the present invention is capable of applying to various semiconductor transistor devices, e.g. planer-trench power MOS (hereinafter called PTMOS) or FinFET. For example, in a PTMOS device, a gate structure is formed by filling a conductive material into the trench (not shown). It is known that a surface 30a of the substrate 10 exposed from the trench 30 has some damages resulting from the step of forming the trench 30. Applicant found that a sacrificial layer 31 may be used to remove the damage of the surface 30a. Namely, the sacrificial layer 31 is formed on an inner surface 30b of the trench 30 resulting from conducting a chemical reaction taken place between an oxygen gas in direct contact with the surface 30a of the substrate 10 being exposed from the trench 30. Therefore, a portion of the sacrificial layer 31 is formed on the surface 30a and another portion thereof is formed underneath the surface 30a (shown in FIG. 1C). Thus, the surface damage of the trench 30 may be eliminated by removing the sacrificial layer 31. The trench 30, however, would be enlarged as the removal of the sacrificial layer 31 is taken place so that the trench 30 is wider than the opening 201 of the patterned hard mask layer 20. That is, the trench 30 may be covered partially by an exposed part of the patterned hard mask layer 20R adjacent to the trench 30 (shown in FIG. 1D).

In subsequent steps of filling a conductive material into the trench 30 and then of forming the gate structure by removing a portion of the conductive material (not shown), it is most likely that residues of the conductive material are formed on the inner surface 30b of the trench adjacent to the part of the patterned hard mask layer 20R, thus hindering the portion of the conductive material from being removed. Hence, the performance of the PTMOS device may be seriously negatively affected. For solving this problem, the part of the patterned hard mask layer 20R is removed by using phosphoric acid solution so as to pull back a sidewall 20a of the patterned hard mask layer 20 and thus preventing the patterned hard mask layer 20 from partially covering the trench 30. Applicant found that, however, it's not easy to control the dosage and the reaction time of phosphoric acid solution.

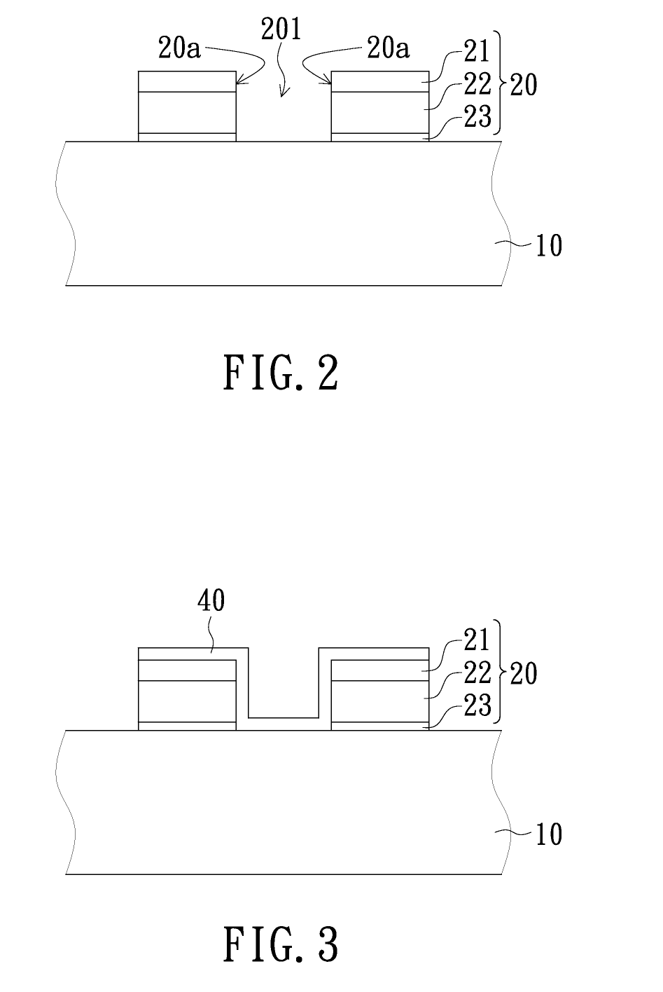

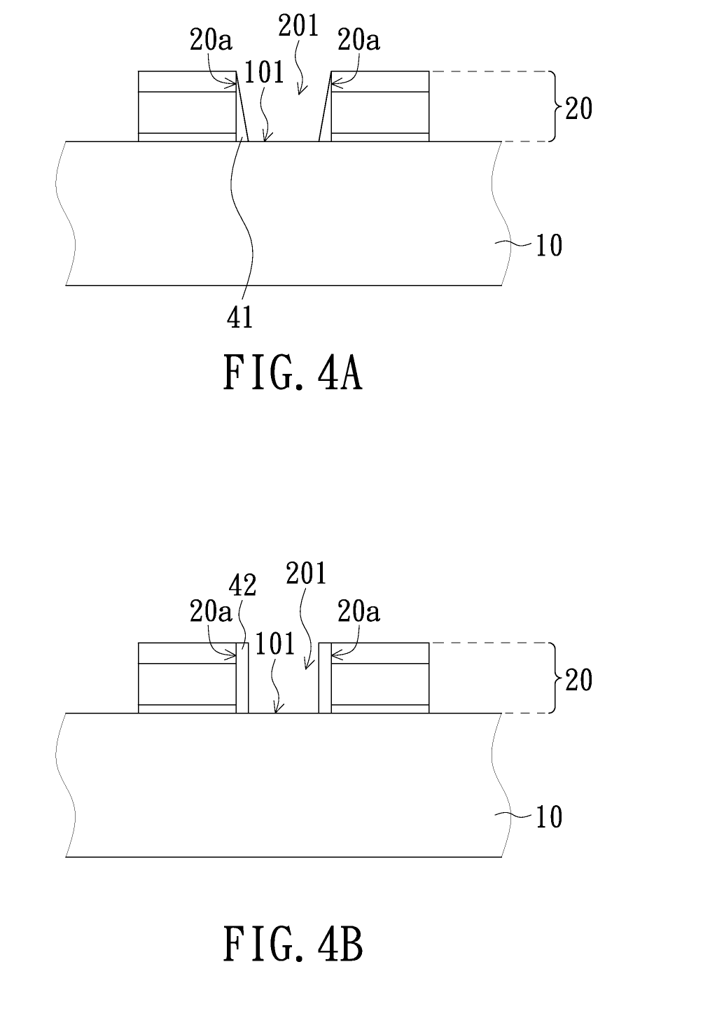

Another embodiment of the present invention is described and shown in FIGS. 2 to 5. Referring to FIG. 2 to FIG. 5, several steps of a process for forming a semiconductor transistor device according to the another embodiment of the present invention is schematically illustrated in cross-sectional view As shown in FIG. 2, the patterned hard mask layer 20 having the opening 201 surrounded by the sidewall 20a is formed on the substrate 10. The patterned hard mask layer 20 may be in the form of multiple dielectric layers, for example, a bottom oxide layer 23, a silicon nitride layer 22, and a top oxide layer 21, formed on the substrate 10 in sequence. Namely, the patterned hard mask layer 20 may be an oxide-nitride-oxide structure (ONO structure). The patterned hard mask layer 20 may be in the form of one dielectric layer. Additionally, in a specified etching condition, an etching rate of the substrate 10 can be ten to hundreds of times higher than an etching rate of the patterned hard mask layer 20.

Next, a spacer is formed on the sidewall 20a of the patterned hard mask layer 20. In the step of forming the spacer, a conformal dielectric layer 40 is formed over the substrate 10 with the patterned hard mask 20. Thus, the sidewall 20a of the patterned hard mask 20 is covered by the dielectric layer 40. The dielectric layer 40 has a thickness equal or less than 150 angstroms. Then, further in the step of spacer formation, an anisotropic etching process of the dielectric layer 40 is then performed to partially expose a surface 101 of the substrate 10 and to leave behind a portion of the dielectric layer 40 on the sidewall 20a of the patterned hard mask layer 20 so as to form a spacer 41 (see FIG. 4A). The dielectric layer 40 is etched using a plasma of gas etchants, e.g. fluorocarbons (CxFy) or fluorinated hydrocarbon (CxHyFz) with inert gas, such as helium, argon, or Xenon, etc. The spacer 41 may have a cross section with a narrow top and a wide bottom, e.g. triangle or trapezoid, and a thickness of the spacer 41 extending from the patterned hard mask 20 may be equal or less than 150 angstroms. Alternatively, the spacer 42 may have a cross section with a substantially identical thickness from a top to a bottom thereof, e.g. rectangle (as shown FIG. 4B), and a thickness of the spacer 42 extending from the patterned hard mask 20 may be equal or less than 150 angstroms.

After that, as shown in FIG. 5, a trench 50 is formed by removing a portion of the substrate 10 not being covered by the patterned hard mask 20 and the spacer 41, in an in-situ etching process. The top oxide layer 21 serves as a hard mask layer for etching the trench 50. Besides, the substrate 10 is etched anisotropically with a plasma of gas etchants, e.g. fluorocarbons (CxFy), fluorinated hydrocarbon (CxHyFz), hydrogen bromide (HBr), bromine (Br₂), chlorine (Cl₂), hydrogen chlorine (HCl), with inert gas, such as helium, argon, or Xenon, etc.

In this embodiment of the present invention, a material of the spacer 41 is selected from a group consisting of silicon dioxide, silicon nitride, silicon carbide and silicon oxynitride. It is to be noted that the substrate 10 is etched with the above gas etchant which results in an etching rate of the substrate 10 ten to hundreds of times higher than an etching rate of the spacer 41. That is, the spacer 41 may serve as a hard mask for defining the trench 50. As a result, an aperture D2 of the trench 50 is shorter than an aperture D1 of the opening 201 of the patterned hard mask layer 20. The difference between the aperture D1 of the opening 201 and the aperture D2 of the trench 50 is substantially equal to the thickness of the spacer 41. Consequently, in this embodiment, the sidewall 20a of the patterned hard mask layer 20 can be pulled back after the spacer 41 is removed so as to solve the problem of the foresaid embodiment.

The process for manufacturing a semiconductor transistor device in this embodiment of the present invention is capable of applying to various semiconductor transistor devices. The particular specific material to be filled in the trench or the depth of the trench which is to be configured would be determined by the requirements depending on the type of the transistor device to be fabricated. For instance, the trench 50 may be filled with a conductive material so as to form a through hole for connecting metal wirings in a semiconductor transistor device or to form a gate structure of a PTMOS device. Alternatively, the trench 50 may be filled with a dielectric material so as to form a trench isolation structure in a semiconductor transistor device. In addition, the depth of the trench ranges between thousands of angstroms and tens of micrometers.

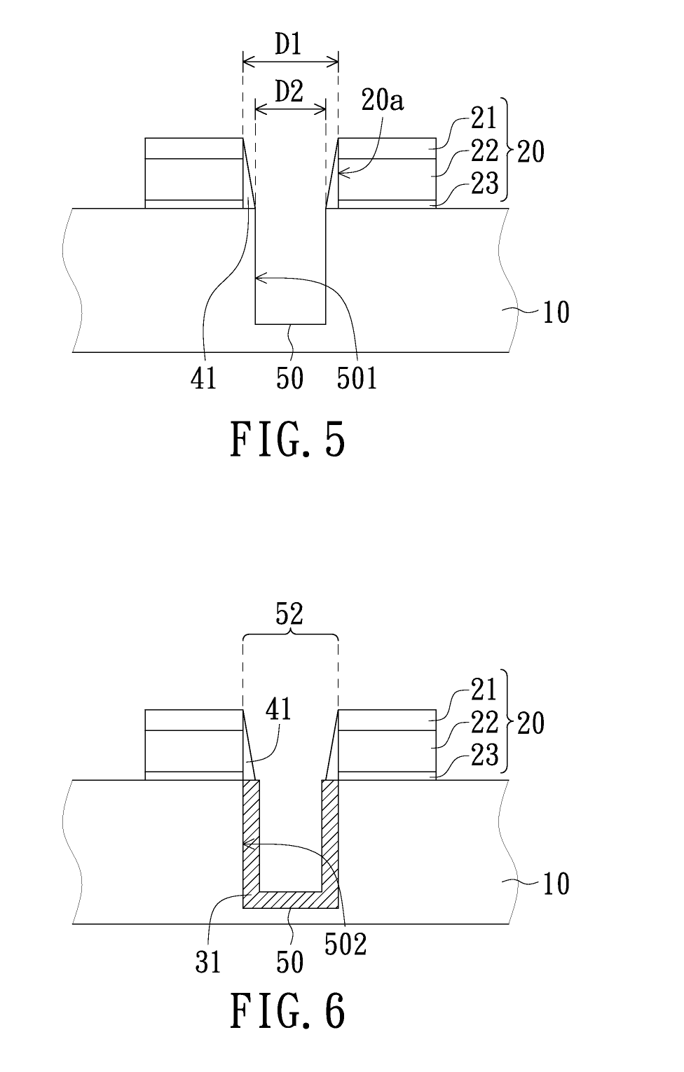

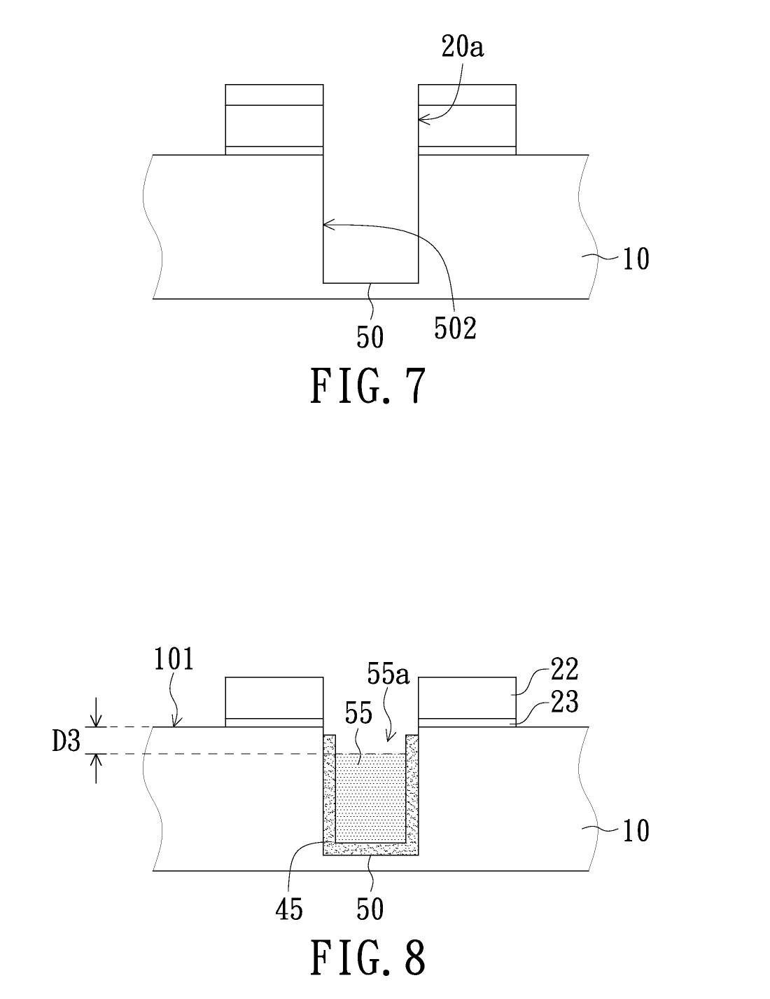

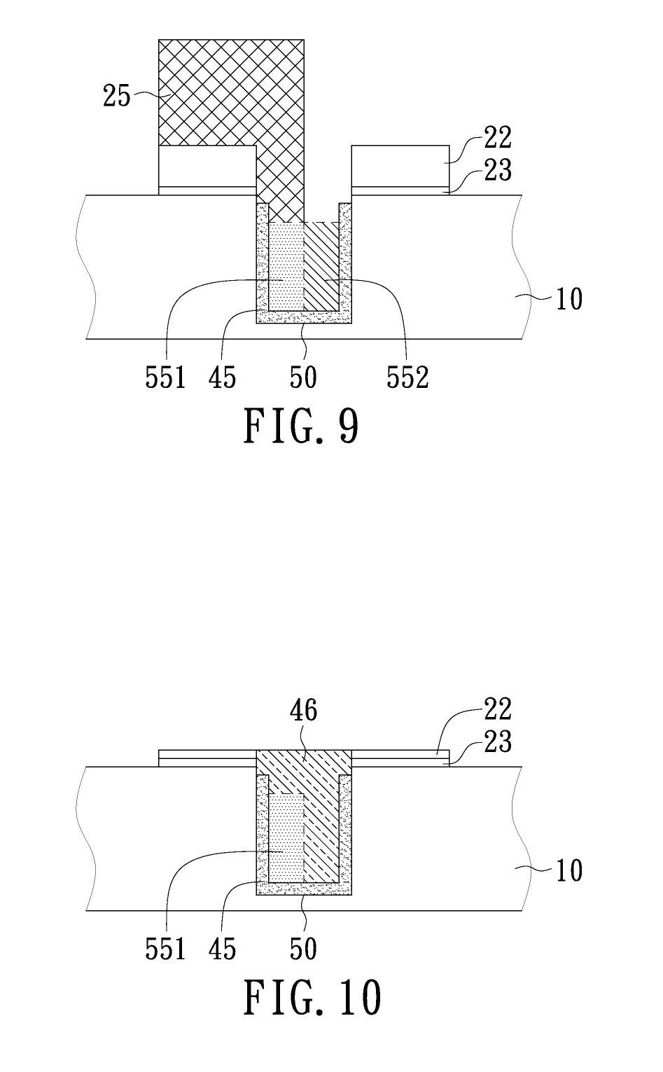

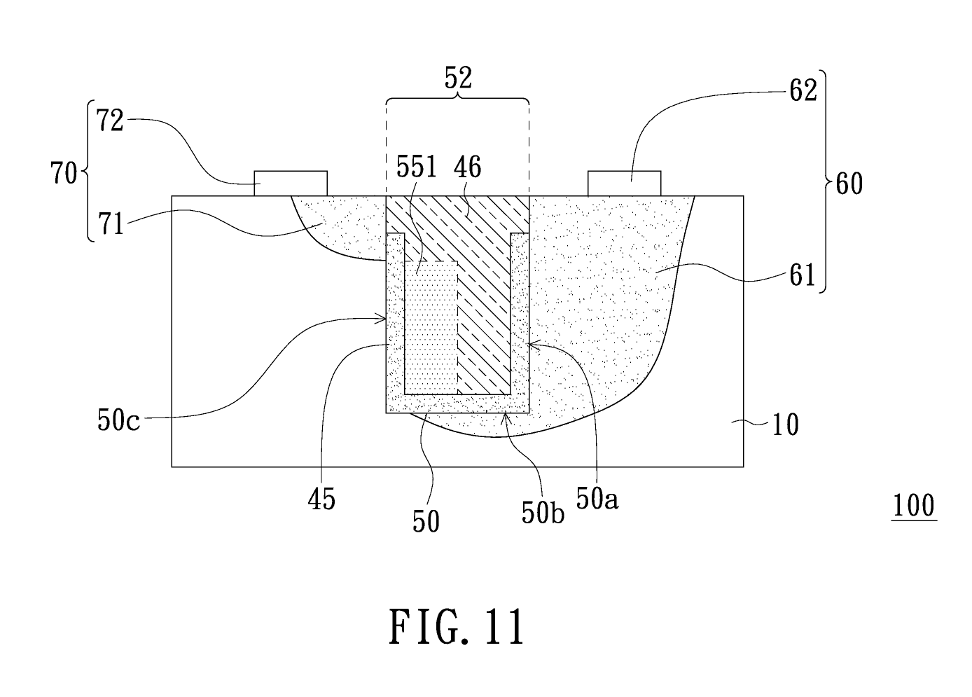

Please see FIG. 6 to FIG. 11, steps of a process for forming a planer-trench power MOS device according to one embodiment of the present invention is schematically illustrated in cross-sectional view. In this embodiment, a gate region 52 is defined by the patterned hard mask 20. As similar to the above embodiment, the trench 50 is formed in the gate region 52. Then, the sacrificial layer 31 is formed on the inner surface 502 of the trench 50 resulting from a chemical reaction conducted between an oxygen gas in contact with a surface 501 of the substrate 10 exposed from the trench 50. Next, the surface damage of the trench 50 may be eliminated by removing the sacrificial layer 31. The spacer 41 and the top oxide layer 21 may be removed as the sacrificial layer 31 is being etched. Alternatively, the step of forming the sacrificial layer 31 may be performedafter the step of removing the spacer 41 and the top oxide layer 21. As mention above, the trench 50 would be enlarged and an inner surface 502 thereof is exposed due to the removal of the sacrificial layer 31. It is to be noted that the spacer 41 formed on the sidewall 20a of the patterned hard mask layer 20 may be regard as a hard mask. Hence an aperture D2 of the trench 50 is narrower than an aperture D1 of the opening 201 of the patterned hard mask layer 20 (see FIG. 5). That is, this embodiment of the present invention is capable of shrinking the trench 50 in advance. When the trench 50 is enlarged resulting from the removal of the sacrificial layer 31, the patterned hard mask layer 20 and the trench 50 are corresponding to each other and both apertures are substantially the same, so that the trench 50 would not be covered by the patterned hard mask layer 20 (as shown in FIG. 7).

Subsequently, a first oxide layer 45 is formed on the inner surface 502 of the trench 50, as shown in FIG. 8, serving as a gate oxide layer. Then, a conductive material 55 is filled into the trench 50 and covering the first oxide layer 45. The trench 50 is filled with the conductive material 55 by chemical vapor deposition (called CVD) or high density plasma CVD. Once the conductive material 55 is filled into the trench 50 and beyond the silicon nitride layer 22 of the hard mask layer, the conductive material 55 and the silicon nitride layer 22 may be configured to be coplanar by performing a planarization process, e.g. a chemical mechanical polishing process. Next, an etching back process is performed to remove a top portion of the conductive material 55 so as to create a recess 55a of tens to hundreds of nanometers in a depth D3, wherein the depth D3 is compared to the surface 101 of the substrate. The recess 55a preferably has the depth D3 of 150 nanometers. Besides, the silicon nitride layer 22 may serve as a stop layer for the planarization process and as a hard mask layer for the etching back process. Nevertheless, the silicon nitride layer 22 is likely to be consumed partially in the etching back process.

Next, referring to FIG. 9, the conductive material 55 is etched under the recess 55a to form a gate structure 551. The gate structure 551 may be defined by a lithography process; for example, a portion 552 of the conductive material 55 that is not covered by a photoresist 25, is etched and another portion of the conductive material 55 that is covered by the photoresist 25, is remained or left behind to form the gate structure 551. Then, a second oxide layer 46 is filled into the trench 50 and covering the gate structure 551. Subsequently, a planarization process of the second oxide layer 46 is performed so that the second oxide layer 46 is coplanar with the silicon nitride layer 22 (as shown in FIG. 10). Additionally, the silicon nitride layer 22 and the bottom oxide layer 23 may be removed completely by an etching process.

Importantly, the sidewall 20a of the patterned hard mask 20 can be pulled back because of the spacer 41 being formed. Since the conductive material 55 in the trench 50 would not be covered by the patterned hard mask 22, it is capable of preventing the residues of the conductive material 55 from forming on the inner surface of the trench 50 in the etching back process or the etching process. Consequently, the performance of the transistor device may be enhanced effectively.

Moreover, the conductive material 55 may be polysilicon so as to form a polysilicon gate structure. The conductive material 55 may be doped with the fifth group of elements, such as, phosphorous, to increase the conductivity of the conductive material 55. The doping process and the step of forming the conductive material 55 may be performed simultaneously; or the doping process of the conductive material 55 may be performed subsequent to the step of forming the conductive material 55; or the doping process may be performed subsequent to the step of forming the gate structure 551.

With reference to FIG. 11, in this embodiment, a drain region 60 and a source region 70 are formed in the substrate 10. A drain structure 61 in the drain region 60 is formed by implanting dopants into the substrate 10 at a first side 50a of the gate region 52 and extending underneath the gate region 52 (where a bottom 50b of the gate region 52 is located). A source structure 71 in the source region 70 is formed by implanting dopants into the substrate at a second side 50c. In addition, the substrate 10 may be doped to form a first conductivity type; the source structure 71 and the drain structure 61 may be of a second conductivity type, wherein the first conductivity type is different from the second conductivity type. For example, the first conductivity type may be doped with the third group elements so as to form P type semiconductor substrate; the second conductivity type may be doped with the fifth group elements so as to form N type semiconductor material. Also, a drain electrode 62 and a source electrode 72 are disposed over the substrate 10, and are separately in contact with the drain structure 61 and the source structure 71, respectively, thereby manufacturing the PTMOS device 100 of the embodiment. The gate structure 551 disposed in the trench 50 of thousands of angstroms to tens of micrometers in depth has an elongated channel for raising the breakdown voltage of the PTMOS device 100.

Furthermore, the trench 50 formed by one embodiment of the process for manufacturing a semiconductor transistor device of the present invention may service as a through hole penetrating the substrate 10 (not shown). The conductive material is filled into the through hole for connecting metal wirings, wherein the conductive material may be made of copper, tungsten, or polysilicon. The trench 50 may be etched to penetrate the substrate 10. Alternatively, the through hole formed to penetrate the substrate 10 may result from etching the trench 50 and then polishing the substrate 10. Because the dimensions of the transistor devices are shrinking, the aspect ratio of the through hole becomes higher, which resulting in more difficulty of filling the conductive material into the through hole. However, the embodiment of the present invention is capable of achieving the desired effect of pulling back the patterned hard mask layer 20. In other words, it becomes easier to fill the conductive material into the through hole due to the patterned hard mask layer 20 having the aperture of the opening 201 greater than the aperture of the through hole. As a result, the embodiment of the present invention may avoid from forming gaps or voids in the through hole. Incidentally, after the conductive material is filled, the patterned hard mask layer and the spacer may be removed.

One embodiment of the manufacturing process in the instant invention may apply to manufacturing other transistor devices, e.g. a FinFET device or a CMOS device. For example, the trench isolation structure is formed by filling a dielectric material, such as, an oxide compound, into the trench 50 (not shown). Then the patterned hard mask layer 20 and the spacer 41 may be removed. The trench isolation structure may serve as a shallow trench isolation (SIT) or a deep trench isolation (DTI) in the FinFET device or the CMOS device. Similar to the above reason, it's difficult to fill the dielectric material into the trench 50. However, it becomes easier to fill the dielectric material into the trench 50 due to the patterned hard mask layer 20 having the aperture of the opening 201 greater than the aperture of the trench 50. Consequently, the trench isolation structure of the embodiment with good quality may improve the performance of the device.

In the long run, according to the present invention, the trench is formed by disposing the patterned hard mask layer over the substrate so as to prevent the substrate from partially deforming. Particularly, the trench is formed after the spacer is formed on the sidewall of the patterned hard mask in order to pull back the patterned hard mask. It is particularly advantageous over the process described in the background for manufacturing a semiconductor transistor device for filling a material into the trench and forming the gate structure of the PTMOS. Hence, the embodiments of present invention may be capable of enhancing the performance of the semiconductor transistor device effectively.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A process for manufacturing a semiconductor transistor device, comprising steps of:
providing a substrate;
forming a patterned hard mask on the substrate;
forming a spacer on a sidewall of the patterned hard mask;
forming a trench by removing a portion of the substrate not being covered by the patterned hard mask and the spacer; and
filling a conductive material into the trench.

2. The process according to claim 1, wherein the step of forming the spacer comprises:
forming a conformal dielectric layer over the substrate with the patterned hard mask; and
forming the spacer on the sidewall of the patterned hard mask by anisotropically etching the dielectric layer.

3. The process according to claim 1, wherein the substrate is anisotropically etched with a specified gas etchant, which results in an etching rate of the substrate ten to hundreds of times higher than an etching rate of the spacer.

4. The process according to claim 1, wherein the spacer has a rectangular cross section, and a thickness of the spacer extending from the patterned hard mask is equal or less than 150 angstroms.

5. The process according to claim 1, wherein the spacer has a triangular or trapezoid cross section, and a thickness of the spacer extending from the patterned hard mask is equal or less than 150 angstroms.

6. The process according to claim 1, further comprising, before the step of filling the conductive material, steps of:
forming a sacrificial layer on an inner surface of the trench resulting from conducting a reaction taken place between an oxygen gas in contact with the substrate;
exposing the inner surface of the trench by removing the sacrificial layer; and
forming a first oxide layer on the inner surface of the trench.

7. The process according to claim 1, further comprising, after the step of filling the conductive material, steps of:
performing a planarization process and an etching back process of the conductive material to remove a top portion of the conductive material so as to create a recess of tens to hundreds of nanometers in depth;
etching the conductive material under the recess to form a gate structure; and
filling a second oxide layer into the trench to cover the gate structure.

8. The process according to claim 1, wherein the trench is formed in a gate region for forming a gate structure, and the process further comprises steps of:
forming a drain structure in a drain region of the substrate disposed at a first side of the gate region and extending underneath the gate region; and
forming a source structure in a source region of the substrate at a second side of the gate region, thereby manufacturing a planer-trench power MOS (PTMOS) device.

9. The process according to claim 8, further comprising steps of:
doping the gate structure, wherein the gate structure is made of polysilicon;
doping the substrate as a first conductivity type; and
doping the source/drain structure as a second conductivity type, wherein the first conductivity type is different from the second conductivity type.

10. The process according to claim 1, wherein a material for forming the spacer is selected from a group consisting of silicon dioxide, silicon nitride, silicon carbide and silicon oxynitride, and a depth of the trench ranges between thousands of angstroms and tens of micrometers.

11. The process according to claim 1, wherein the trench is a through hole penetrating the substrate.

12. A process for manufacturing a semiconductor transistor device, comprising steps of:
providing a substrate;
forming a patterned hard mask on the substrate;
forming a spacer on a sidewall of the patterned hard mask;
forming a trench by removing a portion of the substrate not being covered by the patterned hard mask and the spacer; and
forming a trench isolation structure by filling a dielectric material into the trench.

13. The process according to claim 12, wherein the step of forming the spacer comprises:
forming a conformal dielectric layer over the patterned hard mask; and
forming the spacer on the sidewall of the patterned hard mask by anisotropically etching the dielectric layer.

14. The process according to claim 12, wherein the substrate is anisotropically etched with a specified gas etchant, which results in an etching rate of the substrate ten to hundreds of times higher than an etching rate of the spacer.

15. The process according to claim 12, wherein the spacer has a rectangular cross section, and the thickness of the spacer extending from the patterned hard mask is equal or less than 150 angstroms.

16. The process according to claim 12, wherein the spacer has a triangular or trapezoid cross section, and the thickness of the spacer extending from the patterned hard mask is equal or less than 150 angstroms.

17. The process according to claim 12, wherein a material for forming the spacer is selected from a group consisting of silicon dioxide, silicon nitride, silicon carbide, or silicon oxynitride, and a depth of the trench ranges between thousands of angstroms and tens of micrometers.

18. The process according to claim 12, wherein the trench isolation structure is disposed in a FinFET device or a CMOS device.
